(19) United States
(12) Patent Application Publication
(10) Pub. No.: US 2012/0011423 A1
(43) Pub. Date: Jan. 12, 2012

(54) SILENT ERROR DETECTION IN SRAM-BASED FPGA DEVICES

(76) Inventor: Mehdi Entezari, Collegeville, PA (US)

(21) Appl. No.: 12/833,956

(22) Filed: Jul. 10, 2010

(51) Int. Cl. H03M 13/09; G06F 11/10

(52) U.S. Cl. 714/807; 714/E11.032

(57) ABSTRACT

Methods and systems for detecting errors in a field programmable gate array are disclosed. One method includes applying a cyclic redundancy check value to a transaction, the transaction including an address and data associated with the address. The method also includes applying a cyclic redundancy check value prior to routing the transaction through a field programmable gate array, and checking the cyclic redundancy check value after routing the transaction through the field programmable gate array to detect errors in the field programmable gate array.

### TECHNICAL FIELD

The present disclosure relates to detection of circuit errors. In particular, the present disclosure relates to detection of silent errors in SRAM-based FPGA devices.

### BACKGROUND

A field-programmable gate array (FPGA) is an integrated circuit designed to be configured by the customer or designer after manufacturing. FPGAs contain programmable logic components called “logic blocks”, and a hierarchy of reconfigurable interconnects that allow the blocks to be logically interconnected. In most FPGAs, the logic blocks also include memory elements, which may be simple flip-flops or more complete blocks of memory. By programming the logic blocks in an FPGA, the logic blocks can be configured and combined to perform complex combinational functions.

Increasingly, FPGAs are becoming attractive for implementing new digital logic designs, as compared to standard application-specific integrated circuits (ASICs). This is because, among other reasons, newer FPGAs built using newer process technologies (e.g., 65 nm and smaller gate technologies) are more capable of supporting the higher operating clock frequencies necessitated by today's designs. Additionally, the specific cores included in FPGAs have become more sophisticated and specialized, including “hard” cores such as a PCI-Express or DDR-3 memory controller. Furthermore, the various components included typically will not require license fees or other charges, and therefore such systems appear more attractive for use.

One issue confronted when using SRAM-based FPGAs is the development of silent errors within the device. A silent error is a failure condition that goes undetected in the hardware itself, but causes operational anomalies. Such failures can occur for a number of reasons. One cause of a silent error is degradation of gate speed over time, due to wear of the device. This causes an intermittent problem with a particular cell or transistor in the FPGA, which may affect operation of the FPGA. A second example of a silent error occurs due to the FPGA's vulnerabilities to atmospheric neutrons or other particles introduced into the circuit due to impurities in packaging materials. This second category of silent errors results in one-time errors, referred to as single event upsets (SEUs). Overall, these undetected errors can cause serious data integrity issues within the system.

Various error detection and correction systems exist that have been used to attempt to detect silent errors. However, silent errors can go undetected in FPGAs, even with error correction (e.g., ECC) or detection systems included within the FPGA. One example system includes end-to-end error correction (ECC) protection for data. This arrangement protects a data path, but would not detect or correct an error on an address line, resulting in correct data being written to an erroneous address.

A second system for error detection and correction uses internal dedicated test circuitry in the FPGA device to check the state of CRAM bits against a computed CRC value. In this arrangement, there is a CRC for each configuration frame of CRAM bits. This detection process can take a relatively large time to process (e.g., up to 500 ms), and therefore cannot catch transactions propagated to other computing system components in realtime. Additionally, this technique does not detect errors due to transistor wear-out.

A further system for error detection includes creation and use of completely redundant circuitry, and comparison of output of redundant circuitry to detect errors due to the above-described SEUs and wear-out. This approach is also not advantageous because it involves use of multiple sets of the hardware resources of the original design, and as compared to other approaches.

For these and other reasons, improvements are desirable.

### SUMMARY

In accordance with the following disclosure, the above and other problems are addressed by the following:

In a first aspect, a method of detecting silent errors in a field programmable gate array is disclosed. The method includes applying a cyclic redundancy check value to a transaction prior to routing the transaction through a field programmable gate array, the transaction including an address and data associated with the address, and checking the cyclic redundancy check value after routing the transaction through a field programmable gate array to detect errors in the field programmable gate array.

In a second aspect. a computing system is disclosed that includes an input/output subsystem including a field programmable gate array, as well as a programmable circuit communicatively connected to the input/output subsystem and configured to exchange input/output transactions to the input/output subsystem, each input/output transaction including an address and data. At least one of the input/output subsystem or the programmable circuit is configured to apply a cyclic redundancy check value to each input/output transaction, and wherein the input/output subsystem is configured to check the cyclic redundancy check value output with the input/output transaction from the field programmable gate array to detect errors in the field programmable gate array.

In a third aspect, a field programmable gate array includes a plurality of logic blocks and a configuration memory programmable to define routing among the plurality of logic blocks. The field programmable gate array also includes an input/output connection block communicatively connected to the plurality of logic blocks and the configuration memory, the input/output connection block configured to send and receive transactions including an address and data. The field programmable gate array further includes a cyclic redundancy check circuit configured to apply a cyclic redundancy check value to each transaction received at the input/output connection block and to check the cyclic redundancy check value associated with each transaction to be sent from the input/output connection block to detect errors in the field programmable gate array.

### BRIEF DESCRIPTION OF THE DRAWINGS

FIG. 1 illustrates an example computing system in which aspects of the present disclosure can be implemented;

FIG. 2 is a block diagram illustrating example physical components of a further electronic computing device useable to implement the various methods and systems described herein;

FIG. 3 illustrates an example block diagram of a subsystem of a computing system incorporating a field programmable gate array and implementing error-detection circuitry, according to a possible embodiment of the present disclosure;

FIG. 4 illustrates an example block diagram of a field programmable gate array incorporating error-detection circuitry, according to a possible embodiment of the present disclosure;

FIG. 5 illustrates a diagram of a data block representing a transaction passed through a field programmable gate array, according to a possible embodiment of the present disclosure;

FIG. 6 is a logical block diagram of circuitry used in an FPGA to buffer and route memory addresses and data throughout an FPGA device;

FIG. 7 is a flowchart illustrating an example method for detecting errors in a field programmable gate array, according to a possible embodiment of the present disclosure; and

FIG. 8 is a flowchart illustrating an example method for detecting errors in a field programmable gate array, according to a further possible embodiment of the present disclosure.

### DETAILED DESCRIPTION

Various embodiments of the present invention will be described in detail with reference to the drawings, wherein like reference numerals represent like parts and assemblies throughout the several views. Reference to various embodiments does not limit the scope of the invention, which is limited only by the scope of the claims attached hereto. Additionally, any examples set forth in this specification are not intended to be limiting and merely set forth some of the many possible embodiments for the claimed invention.

The logical operations of the various embodiments of the disclosure described herein are implemented as: (1) a sequence of computer implemented steps, operations, or procedures running on a programmable circuit within a computer, and/or (2) a sequence of computer implemented steps, operations, or procedures running on a programmable circuit within a directory system, database, or compiler.

In general, the present disclosure relates to detection of errors, including silent errors, in a field programmable gate array. In certain embodiments, the present disclosure relates to detection of silent errors in an SRAM-based field programmable gate array (FPGA). The various embodiments described herein relate to application of an error detection code, such as a cyclic redundancy check (CRC) value, to a transaction, including address and data, throughout the time the transaction is passed through the FPGA. By comparing CRC values before and after the FPGA, configuration errors in the FPGA can be detected that are caused by various types of errors, including silent errors.

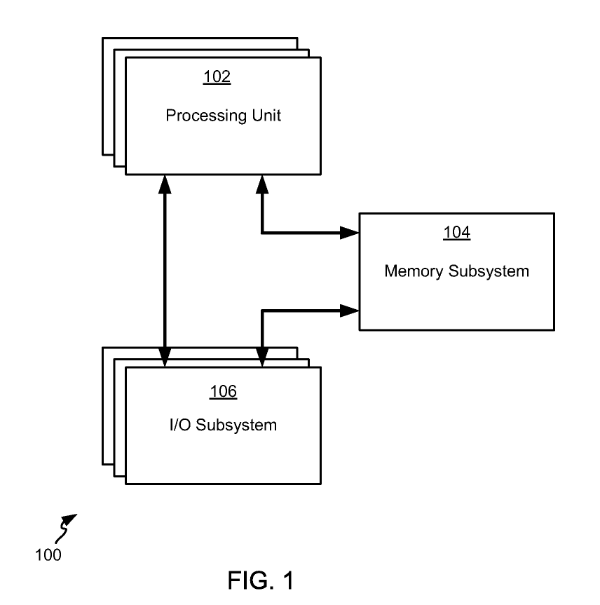

FIG. 1 illustrates an example computing system 100 in which aspects of the present disclosure can be implemented. The example computing system 100 illustrates high-level interconnections among components of the system, specifically as relating to input/output (I/O) and memory transactions processed and distributed among the primary systems included therein. In the embodiment shown, the computing system 100 includes one or more processing units 102 communicatively connected to a memory subsystem 104 and one or more input/output (I/O) subsystems 106. In the embodiment shown, the memory subsystem 104 and I/O subsystems 106 are communicatively interconnected as well.

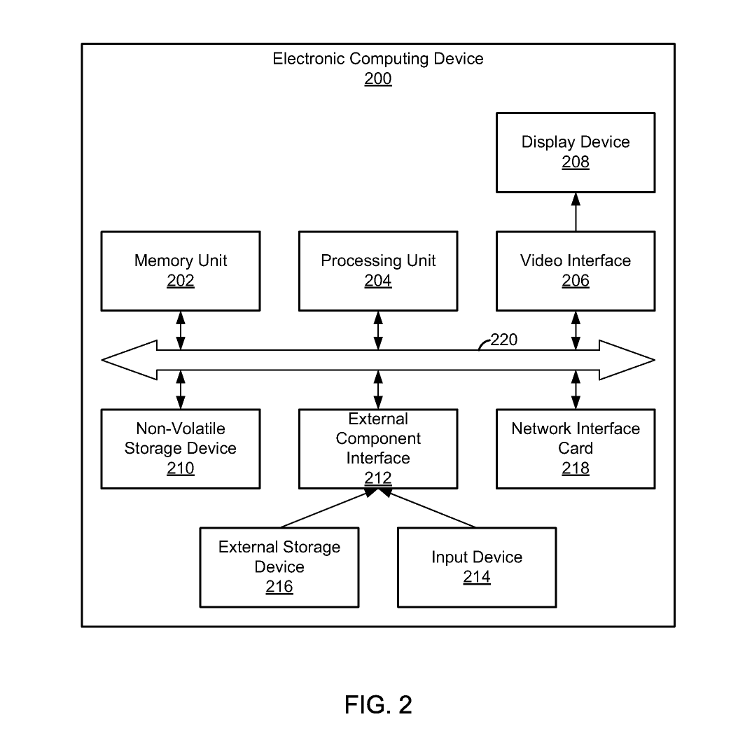

The one or more processing units 102 are configured to execute program instructions that, when executed, cause the computing system 100 to perform specific operations. In some specific embodiments, the processing units 102 can each correspond to common or different types of the processing unit 206 of FIG. 2, below.

The memory subsystem 104 generally corresponds to a unified memory for instructions and data, and therefore represents locations where data is stored as well as storage of an operating system directing operation of the one or more processing units 102, as well as application programs or special purpose applications configured for execution on one or more of the processing units 102. The memory subsystem 104 can include one or more memory devices, such as those described below in connection with FIG. 2.

The I/O subsystems 106 represent systems capable of receiving transactions from one or both of the processing units 102 and the memory subsystem 104, and route those transactions In the context of the present disclosure, the I/O subsystems 106 could route transactions to remote portions of the computing system 100, such as peripheral devices, other processing units, or other types of systems such as those described below in connection with FIG. 2. Consistent with the present disclosure, a transaction refers to an address and associated data, e.g., information with a destination, whether it be to a memory location from one of the processing units 102 or I/O subsystems 106, or from a processing unit 102 to one or more of the I/O subsystems 106.

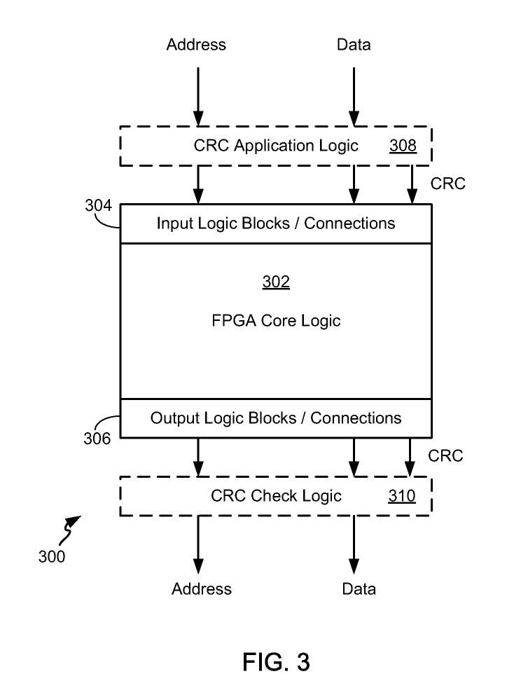

In actual implementation, one or more of the integrated circuits used to implement one of the above subsystems could incorporate one or more field programmable gate arrays (FPGAs) to accomplish the functionality of one or more subsystem. For example, an FPGA could be used to receive and route or process transactions within one or more of the I/O subsystems 106, or could be used as one or more of the processing units 102. In such embodiments, use of FPGAs exposes the computing system 100 to the possibility of errors due to transistor wear out or transient effects, which could result in silent errors (either recurring or one-time errors). In certain embodiments, such as those described below in connection with FIGS. 3-8, methods and systems can be implemented within the computing system 100 to detect silent errors that would typically go undetected within an FPGA.

In various embodiments, each of the subsystems 102-106 of the computing system 100 are interconnected by any of a number of suitable communicative interconnection systems. In certain examples, the processing units 102 and memory subsystem 104 are interconnected via any of a number of communication interfaces (typically processing unit- or memory subsystem-specific, or a combination thereof); the memory subsystem 104 can integrate any of a number of different memory communication interfaces, such as a DDR-3 interface. The I/O subsystems 106 can be interconnected to the memory subsystem 104 and processing units 102 by any of a variety of chip interconnects interfaces, and can include I/O interconnects to peripheral devices, such as a PCI-Express or other type of connection. Other communicative interconnections could be used as well.

FIG. 2 is a block diagram illustrating example physical components of an electronic computing device 200, which can be used to execute the various operations described above, and provides an illustration of further details regarding computing system 100 of FIG. 1. A computing device, such as electronic computing device 200, typically includes at least some form of computer-readable media. Computer readable media can be any available media that can be accessed by the electronic computing device 200. By way of example, and not limitation, computer-readable media might comprise computer storage media and communication media.

As illustrated in the example of FIG. 2, electronic computing device 200 comprises a memory unit 202. Memory unit 202 is a computer-readable data storage medium capable of storing data and/or instructions. Memory unit 202 may be a variety of different types of computer-readable storage media including, but not limited to, dynamic random access memory (DRAM), double data rate synchronous dynamic random access memory (DDR SDRAM), reduced latency DRAM, DDR2 SDRAM, DDR3 SDRAM, Rambus RAM, or other types of computer-readable storage media.

In addition, electronic computing device 200 comprises a processing unit 204. As mentioned above, a processing unit is a set of one or more physical electronic integrated circuits that are capable of executing instructions. In a first example, processing unit 204 may execute software instructions that cause electronic computing device 200 to provide specific functionality. In this first example, processing unit 204 may be implemented as one or more processing cores and/or as one or more separate microprocessors. For instance, in this first example, processing unit 204 may be implemented as one or more Intel Core 2 microprocessors. Processing unit 204 may be capable of executing instructions in an instruction set, such as the x86 instruction set, the POWER instruction set, a RISC instruction set, the SPARC instruction set, the IA-64 instruction set, the MIPS instruction set, or another instruction set. In a second example, processing unit 204 may be implemented as an ASIC that provides specific functionality. In a third example, processing unit 204 may provide specific functionality by using an ASIC and by executing software instructions.

Electronic computing device 200 also comprises a video interface 206. Video interface 206 enables electronic computing device 200 to output video information to a display device 208. Display device 208 may be a variety of different types of display devices. For instance, display device 208 may be a cathode-ray tube display, an LCD display panel, a plasma screen display panel, a touch-sensitive display panel, a LED array, or another type of display device.

In addition, electronic computing device 200 includes a non-volatile storage device 210. Non-volatile storage device 210 is a computer-readable data storage medium that is capable of storing data and/or instructions. Non-volatile storage device 210 may be a variety of different types of non-volatile storage devices. For example, non-volatile storage device 210 may be one or more hard disk drives, magnetic tape drives, CD-ROM drives, DVD-ROM drives, Blu-Ray disc drives, or other types of non-volatile storage devices.

Electronic computing device 200 also includes an external component interface 212 that enables electronic computing device 200 to communicate with external components. As illustrated in the example of FIG. 2, external component interface 212 enables electronic computing device 200 to communicate with an input device 214 and an external storage device 216. In one implementation of electronic computing device 200, external component interface 212 is a Universal Serial Bus (USB) interface. In other implementations of electronic computing device 200, electronic computing device 200 may include another type of interface that enables electronic computing device 200 to communicate with input devices and/or output devices. For instance, electronic computing device 200 may include a PS/2 interface. Input device 214 may be a variety of different types of devices including, but not limited to, keyboards, mice, trackballs, stylus input devices, touch pads, touch-sensitive display screens, or other types of input devices. External storage device 216 may be a variety of different types of computer-readable data storage media including magnetic tape, flash memory modules, magnetic disk drives, optical disc drives, and other computer-readable data storage media.

In the context of the electronic computing device 200, computer storage media includes volatile and nonvolatile, removable and non-removable media implemented in any method or technology for storage of information such as computer readable instructions, data structures, program modules or other data. Computer storage media includes, but is not limited to, various memory technologies listed above regarding memory unit 202, non-volatile storage device 210, or external storage device 216, as well as other RAM, ROM, EEPROM, flash memory or other memory technology, CD-ROM, digital versatile disks (DVD) or other optical storage, magnetic cassettes, magnetic tape, magnetic disk storage or other magnetic storage devices, or any other medium that can be used to store the desired information and that can be accessed by the electronic computing device 200.

In addition, electronic computing device 200 includes a network interface card 218 that enables electronic computing device 200 to send data to and receive data from an electronic communication network. Network interface card 218 may be a variety of different types of network interface. For example, network interface card 218 may be an Ethernet interface, a token-ring network interface, a fiber optic network interface, a wireless network interface (e.g., WiFi, WiMax, etc.), or another type of network interface.

Electronic computing device 200 also includes a communications medium 220. Communications medium 220 facilitates communication among the various components of electronic computing device 200. Communications medium 220 may comprise one or more different types of communications media including, but not limited to, a PCI bus, a PCI Express bus, an accelerated graphics port (AGP) bus, an Infiniband interconnect, a serial Advanced Technology Attachment (ATA) interconnect, a parallel ATA interconnect, a Fiber Channel interconnect, a USB bus, a Small Computer System Interface (SCSI) interface, or another type of communications medium.

Communication media, such as communications medium 220, typically embodies computer-readable instructions, data structures, program modules or other data in a modulated data signal such as a carrier wave or other transport mechanism and includes any information delivery media. The term “modulated data signal” refers to a signal that has one or more of its characteristics set or changed in such a manner as to encode information in the signal. By way of example, and not limitation, communication media includes wired media such as a wired network or direct-wired connection, and wireless media such as acoustic, RF, infrared, and other wireless media. Combinations of any of the above should also be included within the scope of computer-readable media. Computer-readable media may also be referred to as computer program product.

Electronic computing device 200 includes several computer-readable data storage media (i.e., memory unit 202, non-volatile storage device 210, and external storage device 216). Together, these computer-readable storage media may constitute a single data storage system. As discussed above, a data storage system is a set of one or more computer-readable data storage mediums. This data storage system may store instructions executable by processing unit 204. Activities described in the above description may result from the execution of the instructions stored on this data storage system. Thus, when this description says that a particular logical module performs a particular activity, such a statement may be interpreted to mean that instructions of the logical module, when executed by processing unit 204, cause electronic computing device 200 to perform the activity. In other words, when this description says that a particular logical module performs a particular activity, a reader may interpret such a statement to mean that the instructions configure electronic computing device 200 such that electronic computing device 200 performs the particular activity.

One of ordinary skill in the art will recognize that additional components, peripheral devices, communications interconnections and similar additional functionality may also be included within the electronic computing device 200 without departing from the spirit and scope of the present invention as recited within the attached claims.

FIG. 3 illustrates an example block diagram of a subsystem 300 of a computing system incorporating a field programmable gate array and implementing error-detection circuitry, according to a possible embodiment of the present disclosure. The subsystem 300 can be included in any of a number of locations within a computing system such as within one or more I/O subsystems 106 as illustrated in FIG. 1, or any of the various interfaces (e.g., the external component interface 212, vide interface 206, network interface card 218, or other subsystem) of the electronic computing device 200 of FIG. 2.

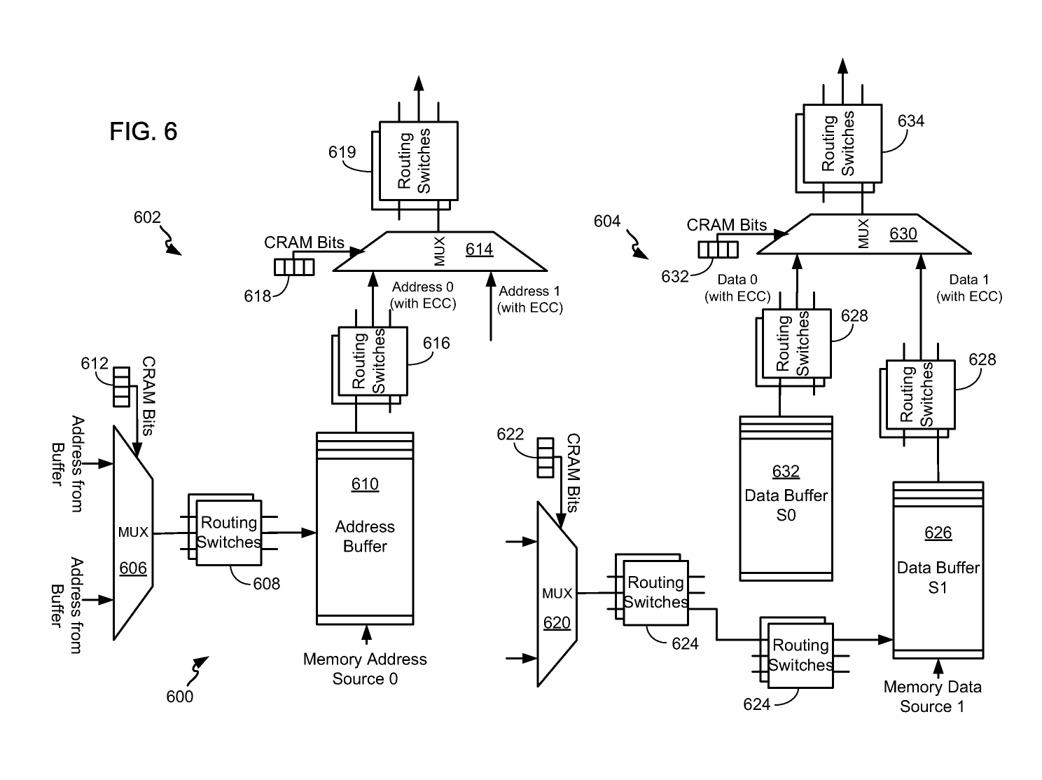

In the embodiment shown, the subsystem 300 includes a field programmable gate array 302 configurable to receive transactions, including address and data, and route those transactions to other systems (e.g., I/O devices or other subsystems). In some embodiments, the field programmable gate array 302 is an SRAM-based field programmable gate array including a configuration RAM used to define routing through the FPGA, for example, by defining routing through multiplexers and/or routing switches as illustrated in the example provided in FIG. 6, below.

In the embodiment shown, the field programmable gate array 302 includes a plurality of logic blocks used as input and output connections, illustrated as input block 304 and output block 306. It is noted that, although these logical blocks are illustrated as input and output blocks, the blocks may not be configured for unidirectional communication, but instead could provide bidirectional communication of transactions with one or more different (or same) subsystems external to the FPGA device; however for purposes of explanation of the error detection systems described herein, the logical blocks 304, 306 are described in terms of input and output functionality.

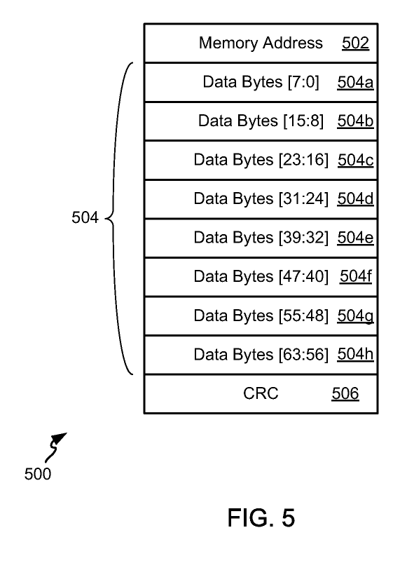

In the embodiment shown, the subsystem 300 includes CRC logic, including CRC application logic 308 and CRC check logic 310. In this embodiment, the CRC application logic 308 receives a transaction from an external system applies a cyclic redundancy check (CRC) value to a transaction, accounting for both address and data included in the transaction. The CRC application logic 308 then passes the transaction and associated CRC value to the field programmable gate array 302, for example as illustrated in the data block illustrated in FIG. 5, below. In certain embodiments, the CRC application logic 308 also checks the CRC value against the transaction prior to sending the transaction and CRC value to the FPGA, as described in connection with the CRC check logic 310, below.

In the embodiment shown, the CRC check logic 310 checks the CRC value against the transaction after it is received from the FPGA 302. In certain embodiments, the CRC check logic 310 generates a checksum or other CRC value based on the transaction received from the FPGA, and compares that checksum against the CRC value transmitted alongside the transaction. If the CRC value generated by CRC check logic 310 does not match that applied by the CRC application logic 308, an error has occurred during interim processing (i.e., within the FPGA 302).

The CRC application logic 308 and CRC check logic 310 (collectively, CRC logic 308, 310) can be implemented any of a number of ways within the subsystem 300. For example, in certain embodiments the CRC logic 308, 310 can be implemented in discrete circuitry communicatively connected at either side of the FPGA to isolate operation of the FPGA. In other embodiments, the CRC logic 308, 310 can be implemented within other computing systems or subsystems communicatively connected to the FPGA, for example within a processing unit or memory subsystem, as described above with respect to FIGS. 1-2. In certain embodiments, one or more portions of the CRC logic 308, 310 is implemented in a memory controller included within a memory subsystem, such as subsystem 104 of FIG. 1.

Furthermore, with respect to FIG. 3, it is noted that address and data included in a transaction are depicted as separate address and data communicative connections; however, in typical embodiments, the address and data information would be passed to an FPGA over a common set of communicative connections, for example alongside the CRC value; the separated address and data are for purposes of illustration only. Various embodiments and configurations of an FPGA and associated logic are possible consistent with the present disclosure, and as recognized due to the programmability of the various connections to an FPGA device.

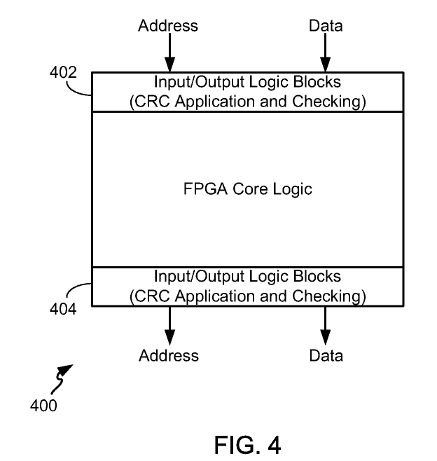

FIG. 4 illustrates an example block diagram of a field programmable gate array 400 incorporating error-detection circuitry, according to a further possible embodiment of the present disclosure. In the embodiment shown, the field programmable gate array 400 includes input/output (I/O) blocks 402, 404, similar to those described above in connection with FIG. 3. The I/O blocks 402, 404 are configured to receive transactions including address and data at the FPGA 400, and route the transactions to various logic blocks within/through the FPGA 400 depending upon its programmed operation. As described with FPGA 302 of FIG. 3, the FPGA 400 can be, in certain embodiments, and SRAM-based FPGA device including a configuration RAM (CRAM) defining routing connections through the FPGA.

In comparison to the embodiment illustrated in FIG. 3, above, CRC application and checking circuitry is contained within the field programmable gate array 400 itself, with the I/O block receiving the transaction applying and optionally initially checking a CRC value, and another I/O block checking the CRC value for an outbound transaction. While this alternative embodiment reduces the amount of logic required by moving the CRC operations within the FPGA itself, the data and address path from (1) input pins of the field programmable gate array, and through the I/O logic block 402 and CRC generation, and from (2) the CRC check and I/O logic block 404 to output pins remain unprotected from silent errors occurring within that circuitry.

FIG. 5 illustrates a diagram of a data block 500 representing a transaction passed through a field programmable gate array, according to a possible embodiment of the present disclosure. In the embodiment shown, the data block includes a transaction including a memory address portion 502 and a data portion 504. In the embodiment shown, the data 504 corresponds to a cache line received from a memory controller at the memory address portion 502, for example as a transaction to be written to a hard disk or sent to another I/O device. In the example shown, the data 504 is from a 64-byte cache line broken into eight 8-byte data blocks 504a-h; however other sizes of cache lines are useable as well, depending upon the architecture of the processing units and memory subsystems included within the computing system in which the data block exists. Additionally, the specific size and arrangement of the data block 500 (e.g., length of address, amount of data included) will vary according to use, for example if the transaction represents a data transaction other than a cache line write to an I/O device or subsystem.

In the embodiment shown, the data block 500 includes a CRC value 506 applied to the transaction. The CRC value 506 is typically a result of a polynomial hash function (e.g., a remainder from polynomial division) using a preselected CRC function. The CRC polynomial selected can take any of a number of forms; the design of the CRC polynomial depends on the maximum total length of the block to be protected, including both the transaction and CRC bits, as well as the desired error protection features and the resources available to implement the CRC. Common polynomial lengths are CRC-8, CRC-16, CRC-32, and CRC-64. Other polynomial lengths could be used as well.

In certain embodiments, a fixed bit pattern is also added to the transaction to be checked, or to be added before the polynomial division/computation occurs. In further embodiments, additional logic can be applied to a remainder to arrive at the CRC value. Other schemes (e.g., byte reordering or other logic) are possible as well.

Now referring to FIG. 6, a logical block diagram of circuitry 600 is illustrated that can be used to buffer and route transactions, including memory addresses and data, throughout an FPGA device. The circuitry 600 is intended to illustrate a location in which silent errors could occur and go undetected in the absence of a CRC check.

In the embodiment shown, the circuitry 600 includes an address routing circuit 602 and a data routing circuit 604. The address routing circuit 602 generally includes a first address multiplexer 606 configured to receive two or more possible addresses (including optional added parity bits or ECC bits) from a previous address buffer, and route those addresses through one or more routing switches 608 to an address buffer 610. The specific routing operation of the first address multiplexer 606 is defined by CRAM bits 612, which are stored in a configuration memory of an FPGA and are intended to control logical interconnections and operation of an SRAM-based FPGA. The address buffer 610 also receives addresses from other sources (illustrated as “Memory Address From Source 0”), for example from a source external to the FPGA. The address buffer 610 passes addresses along to a second address multiplexer 614 via one or more additional routing switches 616. The second address multiplexer 614 selects one of the addresses received based on a second set of CRAM bits 618, for routing through additional routing switches 619.

The addresses received and routed via the address routing circuit 602 can, in certain embodiments, include various additional information, such as error detecting and correcting codes associated therewith. Additionally, it is noted that the address routing circuit 602 represents only an abstracted portion of a data path through an FPGA, and additional logic, routing, and buffering are included as well.

The data routing circuit 604 includes components largely analogous to those included in the address routing circuit 602. In the embodiment shown, the data routing circuit 604 includes a first data multiplexer 620 receiving data (including optional added parity bits or ECC bits) and selecting one of those sets of data based on a configuration determined by CRAM bits 622. The selected data can be, as in the embodiment shown, routed through routing switches 624 to a data buffer 626 (in FIG. 6 illustrated as “Data Buffer S1”). The data buffer 626 can also receive data from other sources (illustrated in the example as “Memory Data from Source 1”). Data in the data buffer 626 can be routed via additional routing switches 628 to a second data multiplexer 630, which selects data from either the data buffer 626 or other source (e.g., data buffer 632) for routing through additional routing switches 634. The second data multiplexer can be controlled by additional CRAM bits 636.

As with the addresses routed by the address routing circuit 602, it is understood that the data routed by the data routing circuit 604 could include additional information, such as error correcting codes, parity bits, or other tracking information.

The following example illustrates an example silent error, and how application of a CRC value across an entire transaction could detect mismatch of address and data due to a silent error occurring in the CRAM bits. Assuming a transaction corresponds to a cache line write to a hard disk or other computing subsystem, a cache line (e.g., 64 bytes) worth of data is intended to be written to address location 0a0b0c0d0e0f00h in the main memory of the system. Also, it is assumed in this example that the width of the buffer used to temporarily store the data is 8 bytes wide with 1 byte of ECC field, although in certain embodiments this may vary. Furthermore, the example assumes that internal RAM buffers in the FPGAs are 72-bits wide, and therefore could contain 8 bytes worth of data.

Taking these assumptions into account, example address and data could be as follows:

| | |
|---|---|
| Address: | 0a0b0c0d0e0f00h |
| Data: | 0102030405060708h |
| | 1112131415161718h |
| | 2122232425262728h |
| | 3132333435363738h |
| | 4142434445464748h |
| | 5152535455565758h |
| | 6162636465666768h |
| | 7172737475767778h |

The data in the data buffer could therefore be organized as:

| RAM Location | Content |
|---|---|
| xy | 0102030405060708h + 8 ECC bits |
| xy+8 | 1112131415161718h + 8 ECC bits |
| xy+16 | 2122232425262728h + 8 ECC bits |
| xy+24 | 3132333435363738h + 8 ECC bits |
| xy+32 | 4142434445464748h + 8 ECC bits |
| xy+40 | 5152535455565758h + 8 ECC bits |
| xy+48 | 6162636465666768h + 8 ECC bits |
| xy+56 | 7172737475767778h + 8 ECC bits |

The main memory address (0a0b0c0d0e0f00h) for this cacheline could be stored in a location in the address buffer 610. The logic in the FPGA is responsible to deliver the cacheline data along with its corresponding memory address to the system memory subsystem. However, as illustrated in the data routing circuit 604, there are typically multiple sources for data that is destined to the memory subsystem (e.g. data buffers 626, 632). There are also a corresponding memory addresses for those data stored in address buffers (e.g. address buffer 610). Only one set of data could at any time be transmitted to or from a memory subsystem; therefore, multiplexers are used in the example circuitry 600 to select between sources and data.

As illustrated in the circuitry 600 and typical within a FPGA, data and address information is routed and treated separately. Assuming the CRAM bits 612, 618, 622, 636 all are correct, the multiplexing through the FPGA occurs correctly, the address and corresponding data for a cache line will synchronously be routed through the FPGA. However, in the case of an error within the FPGA, for example in one of the sets of CRAM bits 612, 618, 622, 636, data or address information could be mis-selected by one of the multiplexers or change operation of one of the routing switches, causing a mismatch between the address and data. This mismatch would not be detected by the error correction or parity bits, which are only applied to an individualized address or data set.

For instance, if a CRAM bit within CRAM bits 632 is affected, then a set of data with correct ECC can be written from another buffer (DataBuffer S0/S1) to memory without raising any error signals:
0102030405060708h+8 ECC bits
1112131415161718h+8 ECC bits
2122232425262728h+8 ECC bits
3132333435363738h+8 ECC bits
4142434445464748h+8 ECC bits
0000000000000000h+8 ECC bits
0000000000000000h+8 ECC bits
0000000000000000h+8 ECC bits

The reason that such an error would be undetected is that the ECC protection is per piece of data (i.e. 8 bytes), and no relationship is made between the entire data packet and its corresponding memory address.

Therefore, as illustrated above, by application of a CRC value to the collective address and data (and passing the CRC value alongside one or both of the address and data), a check can be made to ensure that the address and data are properly paired and that no errors have occurred in the transaction overall.

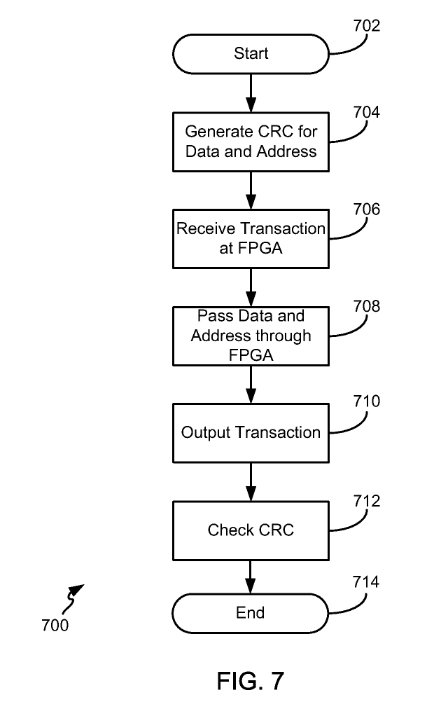

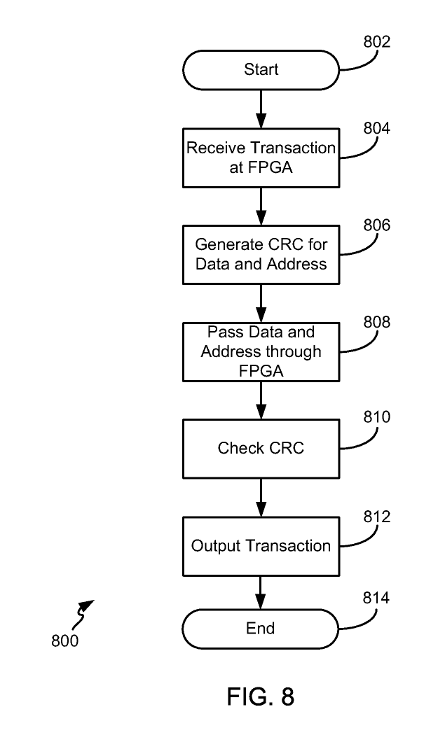

Referring now to FIGS. 7-8, example methods of detecting errors, such as silent errors, in an FPGA are disclosed, according to certain embodiments of the present disclosure. FIG. 7 describes a method for detecting silent errors in an FPGA using logic external to the FPGA, for example as illustrated in FIG. 3; above. FIG. 8 describes a method for detecting silent errors in an FPGA using logic internal to the FPGA, for example as illustrated in FIG. 4.

In general, the method of FIG. 7 illustrates that, prior to sending a transaction to the FPGA, a CRC value is generated to cover the data and its corresponding memory address associated in the cache line or other transaction. The CRC value is checked at both ends of the device or in the external devices that are attached to the FPGA device. In the method of FIG. 8, the CRC value is generated and checked within the FPGA itself, immediately upon receipt and just before transmission, respectively. In both methods, by protecting the address and the corresponding data collectively with a CRC value, any CRAM bit state change or wearout condition that affects the data or the address will be detected.

Referring now to FIG. 7, a method 700 for detecting such silent errors is instantiated at a start operation 702, which refers to receipt of a transaction, including an address and data (e.g., a cache line or some other transaction) at logic external to an FPGA and capable of applying a CRC to that transaction. A CRC generation operation 704 generates a cyclic redundancy check value for a transaction, and appends the CRC value to the transaction for transmission to the FPGA. The CRC generation operation 704 can occur, for example, in CRC application logic external to an FPGA, such as CRC application logic 308 of FIG. 3.

Optionally, the CRC generation operation 704 also performs a CRC check operation on the transaction after applying the CRC value. For example, the CRC generation operation 704 can check that the CRC value is generated properly according to the expected CRC operation selected to be implemented at the CRC logic. If the CRC check operation fails, the CRC value was not properly generated, or some error occurred after its creation in either the CRC value or the transaction to which it is applied.

A transmission operation 706 transmits the transaction to an FPGA, for example FPGA 302 of FIG. 3, above. A routing operation 708 routes the transaction through the FPGA, according to the programmed operation of the FPGA (e.g., as defined at least in part by CRAM bits included in the FPGA). The routing operation 708 corresponds to transfer of the transaction through the FPGA, for example through circuitry such as that shown in FIG. 6, above.

An output operation 710 transmits the transaction from the FPGA to logic external to the FPGA, for example a memory subsystem, other logic within an I/O subsystem, or a processing unit interfaced to the FPGA. A CRC check operation 712 then recalculates a CRC value based on the transaction, and compares the computed CRC value to the CRC value associated with the transaction. If the CRC check operation 712 determines that the CRC value is correct (i.e., is the same as the previously-generated CRC value), no silent error has occurred and the transaction was routed through the FPGA correctly, with address and data matched at both entry into and exit from the FPGA. However, if the CRC check operation 712 computes a CRC value different from that applied by the CRC generation operation 704, then some error has occurred between generation and checking of the CRC value. An end operation 714 corresponds to completed routing of the transaction through an FPGA device.

Referring now to FIG. 8, a method 800 of detecting errors in a field programmable gate array is disclosed, according to a further possible embodiment of the present disclosure. The method 800 generally includes similar operations to the method 700 of FIG. 7, but occurs in a slightly different order due to the fact that the CRC operations are performed within the FPGA. In the embodiment shown, the method 800 is instantiated at a start operation 802, which corresponds to receipt of a transaction in a subsystem of a computing device including an FPGA device, such as the device 400 of FIG. 4. A transmission operation 804 transmits the transaction to an FPGA, for example FPGA 400.

A CRC generation operation 806 generates a cyclic redundancy check value for a transaction, and appends the CRC value to the transaction. The CRC generation operation 806 can occur, for example, in CRC application logic immediately adjacent to or integrated within input/output logic of the FPGA, to maximize the routing within the FPGA in which the CRC value is associated with the transaction.

Optionally, the CRC generation operation 806 also performs a CRC check operation on the transaction after applying the CRC value. For example, the CRC generation operation 806 can check that the CRC value is generated properly according to the expected CRC operation selected to be implemented at the CRC logic. If the CRC check operation fails, the CRC value was not properly generated, or some error occurred after its creation in either the CRC value or the transaction to which it is applied.

A routing operation 808 routes the transaction through the FPGA, according to the programmed operation of the FPGA (e.g., as defined at least in part by CRAM bits included in the FPGA). The routing operation 808 corresponds to transfer of the transaction through the FPGA, for example through circuitry such as that shown in FIG. 6, above.

A CRC check operation 810 then recalculates a CRC value based on the transaction, and compares the computed CRC value to the CRC value associated with the transaction. If the CRC check operation 810 determines that the CRC value is correct (i.e., is the same as the previously-generated CRC value), no silent error has occurred and the transaction was routed through the FPGA correctly, with address and data matched at both “edges” of the FPGA. However, if the CRC check operation 810 computes a CRC value different from that applied by the CRC generation operation 804, then some error has occurred between generation and checking of the CRC value.

An output operation 812 transmits the transaction from the FPGA to logic external to the FPGA, for example a memory subsystem, other logic within an I/O subsystem, or a processing unit interfaced to the FPGA. An end operation 714 corresponds to completed routing of the transaction through an FPGA device.

Referring now to FIGS. 1-8 generally, application of a CRC across an entire transaction as described herein allows detecting silent errors that affect any of the CRAM bits that control, for example, multiplexers within an FPGA that select between different memory address sources, or that select between different memory data sources. This arrangement also provides protection from silent errors in CRAM bits controlling multiplexers arranged to control the address of the buffers used for temporary storage of memory data, or multiplexers that control the address of the buffers used for temporary storage of memory address. Additionally, the CRC as applied to a transaction protects from CRAM bit errors that control routing data and address signals throughout routing switches in the data and address paths. In addition, the CRC protection systems and methods described herein protects against transistor wear out conditions in which the states of control logic get changed temporarily.

Additionally, it can be seen that additional advantages can be gained in applying a CRC value to a transaction routed through a FPGA when used in association with other error detection or correction schemes. For example, in embodiments using end-to-end ECC data protection, the CRC error detection scheme ensures that an unrelated data is not written to an intended location in memory, or a valid data is not written to a wrong location in memory. In embodiments using internal CRC circuitry in an FPGA, the added CRC scheme of the present disclosure catches data corruption in time without allowing it to be consumed by other parts of the system (silent errors). Additionally, in embodiments using redundant circuitry to detect silent errors, the CRC error detection scheme eliminates the need for duplication or triplication of all the logics and the buffering that are needed for the data and addresses throughout the device. This will result in requiring less FPGA resources for duplication and triplication.

The above specification, examples and data provide a complete description of the manufacture and use of the composition of the invention. Since many embodiments of the invention can be made without departing from the spirit and scope of the invention, the invention resides in the claims hereinafter appended.

1. A method of detecting silent errors in a field programmable gate array, the method comprising:
applying a cyclic redundancy check value to a transaction prior to routing the transaction through a field programmable gate array, the transaction including an address and data associated with the address; and
checking the cyclic redundancy check value after routing the transaction through a field programmable gate array to detect errors in the field programmable gate array.

2. The method of claim 1, further comprising transmitting the transaction and cyclic redundancy check value to a field programmable gate array.

3. The method of claim 2, wherein applying the cyclic redundancy check value occurs before transmitting the transaction and cyclic redundancy check value to the field programmable gate array.

4. The method of claim 2, wherein the field programmable gate array is an SRAM-based field programmable gate array.

5. The method of claim 1, further comprising, checking the cyclic redundancy check value prior to routing the transaction through the field programmable gate array.

6. The method of claim 1, wherein applying a cyclic redundancy check value to a transaction is performed in logic communicatively interfaced to the field programmable gate array.

7. The method of claim 1, wherein applying a cyclic redundancy check value to a transaction is performed within the field programmable gate array.

8. The method of claim 1, wherein the errors include errors in the configuration memory of the field programmable gate array.

9. A computing system comprising:
An input/output subsystem including a field programmable gate array;
a programmable circuit communicatively connected to the input/output subsystem and configured to exchange input/output transactions to the input/output subsystem, each input/output transaction including an address and data;
wherein at least one of the input/output subsystem or the programmable circuit is configured to apply a cyclic redundancy check value to each input/output transaction, and wherein the input/output subsystem is configured to check the cyclic redundancy check value output with the input/output transaction from the field programmable gate array to detect errors in the field programmable gate array.

10. The system of claim 9, wherein the errors include silent errors.

11. The system of claim 9, wherein the field programmable gate array is an SRAM-based field programmable gate array.

12. The system of claim 9, wherein applying a cyclic redundancy check value to an input/output transaction is performed within the field programmable gate array.

13. The system of claim 9, wherein the errors include errors in the configuration memory of the field programmable gate array.

14. The system of claim 13, wherein the errors occur in configuration memory controlling one or more routing switches within the field programmable gate array.

15. The system of claim 13, wherein the errors occur in configuration memory controlling one or more multiplexers within the field programmable gate array.

16. The system of claim 9, wherein the input/output subsystem includes circuitry interfaced to the field programmable gate array and is configured to apply a cyclic redundancy check value to each input/output transaction passed to the field programmable gate array.

17. The system of claim 9, wherein the input/output subsystem includes circuitry interfaced to the field programmable gate array and is configured to evaluate a cyclic redundancy check value for each input/output transaction received from the field programmable gate array.

18. A field programmable gate array comprising:
a plurality of logic blocks;
a configuration memory programmable to define routing among the plurality of logic blocks;
an input/output connection block communicatively connected to the plurality of logic blocks and the configuration memory, the input/output connection block configured to send and receive transactions including an address and data; and
a cyclic redundancy check circuit configured to apply a cyclic redundancy check value to each transaction received at the input/output connection block and to check the cyclic redundancy check value associated with each transaction to be sent from the input/output connection block to detect errors in the field programmable gate array.

19. The field programmable gate array of claim 18, wherein the field programmable gate array comprises an SRAM-based field programmable gate array.

20. The field programmable gate array of claim 18, wherein the errors detected by the cyclic redundancy check circuit include silent errors.

21. The field programmable gate array of claim 18, wherein the detected errors occur in configuration memory controlling one or more multiplexers within the field programmable gate array.
